(19) United States
(12) Patent Application Publication
(10) Pub. No.: US 2009/0180335 A1
(43) Pub. Date: Jul. 16, 2009

(54) INTEGRATED CIRCUIT WITH REDUCED POINTER UNCERTAINLY

(76) Inventors: Sivaraman Chokkalingam, San Jose, CA (US); Hamid Partovi, Los Altos, CA (US); Luca Ravezzi, Palo Alto, CA (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/014,452

(22) Filed: Jan. 15, 2008

(51) Int. Cl. G11C 7/00; H03L 7/00; G11C 8/00

(52) U.S. Cl. 365/189.05; 327/144; 365/233.11

(57) ABSTRACT

One embodiment provides an integrated circuit including a first circuit and a second circuit. The first circuit is configured to obtain a sample of a first clock via a second clock and provide a selected clock from multiple clocks based on the sample. The second circuit is configured to provide a first pointer clock based on the first clock and a second pointer clock based on the selected clock. An edge of the second pointer clock relative to an edge of the first pointer clock is limited to an uncertainty range of within one-half a first pointer clock cycle.

### BACKGROUND

Electronic systems usually include a number of integrated circuits that communicate with one another to perform system applications. The integrated circuits can be on the same integrated circuit chip or on separate integrated circuit chips. Often, an electronic system includes one or more host controllers and one or more electronic subsystem assemblies, such as a dual in-line memory module (DIMM), a graphics card, an audio card, a facsimile card, and/or a modem card.

To perform system functions, the host controller and subsystem assemblies communicate via communication links, such as serial communication links and parallel communication links. Serial communication links include links that implement the fully buffered DIMM (FB-DIMM) advanced memory buffer (AMB) standard. Typically, an FB-DIMM includes an AMB chip and random access memory (RAM) chips, such as double data rate dynamic random access memory (DDR-DRAM) chips. The DDR-DRAM chips can be any suitable type and generation of DDR-DRAM. The AMB chip interfaces with the host controller and other FB-DIMMs.

The AMB chip has two serial links, one for upstream traffic and the other for downstream traffic, and a bus to on-board memory, such as DRAM on the FB-DIMM. Serial data from the host controller sent through the downstream serial link (southbound) is temporarily buffered, and then sent to memory in the FB-DIMM. The serial data contains the address, data, and command information given to the memory, converted in the AMB, and sent out to the memory bus. The AMB writes in and reads out from the memory as instructed by the host controller. The read data is converted to serial data, and sent back to the host controller on the upstream serial link (northbound).

The AMB also performs as a repeater between FB-DIMMs on the same channel. The AMB transfers information from a primary southbound link connected to the host controller or an upper AMB to a lower AMB in the next FB-DIMM via a secondary southbound link. The AMB receives information in the lower FB-DIMM from a secondary northbound link, and after merging the information with information of its own, sends it to the upper AMB or host controller via a primary northbound link. This forms a daisy-chain among FB-DIMMs. Attributes of the FB-DIMM channel architecture include the high-speed, serial, point-to-point connection between the host controller and FB-DIMMs on the channel.

Data is often transferred between circuits from one clock domain to another clock domain via first in first out (FIFO) structures. In serial communication links, such as an AMB link, data can be received via a clock and data recovery circuit that recovers the clock embedded in the serial data and retimes the data to the recovered clock. The recovered clock usually has undesirable noise characteristics and further processing of the recovered data with the recovered clock is not feasible. Therefore, the recovered data is transferred to a clean clock domain via a FIFO.

Data is sequentially written into the FIFO via a write pointer clock in one clock domain and read from the FIFO via a read pointer clock in the other clock domain. Often, these two clocks are frequency locked together, but the phase relationship between the active edge of the read pointer clock and the active edge of the write pointer clock is unknown. This uncertainty in the phase relationship, which may be as high as a full clock cycle, increases data latency through the FIFO. In some applications, such as FB-DIMM applications, data latency through the FIFO is critical to the operation of the electronic system and should be minimized.

For these and other reasons there is a need for the present invention.

### SUMMARY

The present disclosure describes an integrated circuit with reduced pointer uncertainly. One embodiment provides an integrated circuit including a first circuit and a second circuit. The first circuit is configured to obtain a sample of a first clock via a second clock and provide a selected clock from multiple clocks based on the sample. The second circuit is configured to provide a first pointer clock based on the first clock and a second pointer clock based on the selected clock. An edge of the second pointer clock relative to an edge of the first pointer clock is limited to an uncertainty range of within one-half a first pointer clock cycle.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of an electronic system according to the present invention.

FIG. 2 is a block diagram illustrating one embodiment of an FB-DIMM.

FIG. 3 is a diagram illustrating one embodiment of an input circuit that receives input data in a first clock domain and provides output data in a second clock domain.

FIG. 4 is a diagram illustrating one embodiment of a data and clock circuit.

FIG. 5 is a diagram illustrating one embodiment of a phase selector.

FIG. 6 is a timing diagram illustrating the operation of the phase selector of FIG. 5.

FIG. 7 is a diagram illustrating one embodiment of a clock pointer circuit.

FIG. 8 is a timing diagram illustrating the operation of a clock pointer circuit, where the resulting spacing between write pointers and read pointers is one clock.

FIG. 9 is a timing diagram illustrating the operation of a clock pointer circuit, where the resulting spacing between write pointers and read pointers is one and a half clock periods.

FIG. 10 is a diagram illustrating another embodiment of a clock pointer circuit.

FIG. 11 is a timing diagram illustrating the operation of a clock pointer circuit, where the resulting spacing between write pointers and read pointers is half a clock.

FIG. 12 is a timing diagram illustrating the operation of a clock pointer circuit, where the resulting spacing between write pointers and read pointers is about one clock.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

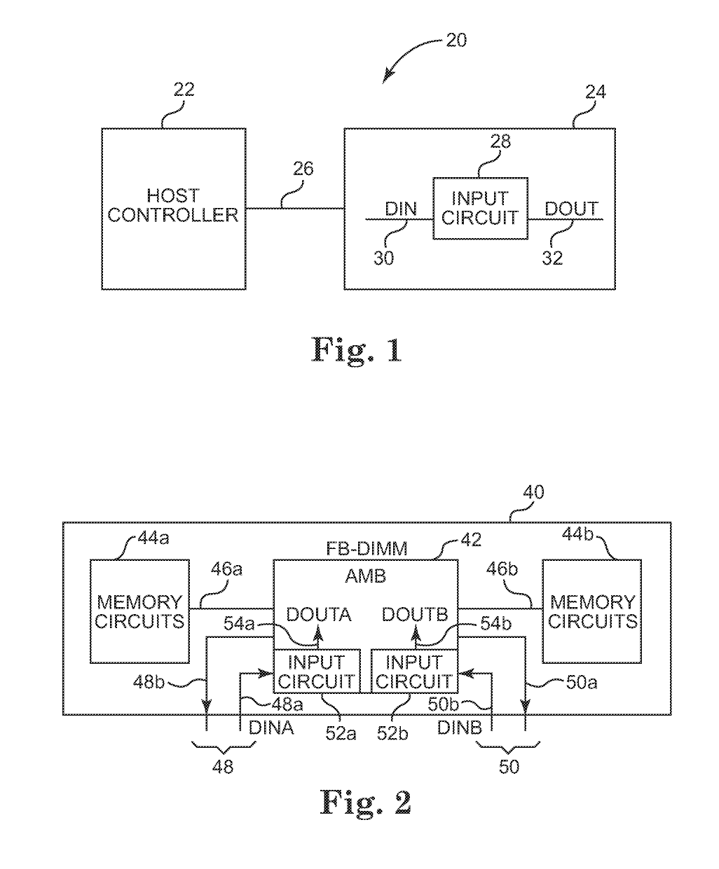

FIG. 1 is a diagram illustrating one embodiment of an electronic system 20 according to the present invention. Electronic system 20 includes a host controller 22 and a subsystem assembly 24. Host controller 22 is electrically coupled to subsystem assembly 24 via communications link 26. In one embodiment, subsystem assembly 24 includes multiple integrated circuit chips. In one embodiment, subsystem assembly 24 is a single integrated circuit chip.

Host controller 22 controls subsystem assembly 24 via communications link 26 to provide one or more system functions. In one embodiment, host controller 22 is a memory controller. In one embodiment, subsystem assembly 24 is an FB-DIMM and host controller 22 controls the FB-DIMM to provide a system memory function. In other embodiments, subsystem assembly 24 can be any suitable subsystem assembly, such as a graphics card, an audio card, a facsimile card, or a modem card, and host controller 22 controls subsystem assembly 24 to provide the corresponding system function.

Subsystem assembly 24 includes an input circuit 28 that receives input data DIN at 30 in a first clock domain and provides output data DOUT at 32 in a second clock domain. Input circuit 28 samples a first clock in the first clock domain via a second clock in the second clock domain to obtain a phase relationship between the first clock and the second clock. Based on the phase relationship between the first clock and the second clock, input circuit 28 selects one clock of multiple clocks in the second clock domain such that an edge of the selected clock relative to an edge of the first clock is limited to an uncertainty range of one-half a first clock cycle. In one embodiment, the multiple clocks in the second clock domain include the second clock and one or more clocks having different phase relationships to the second clock.

Input circuit 28 provides a first pointer clock based on the first clock and a second pointer clock based on the selected clock, where an edge of the second pointer clock relative to an edge of the first pointer clock is limited to the uncertainty range of within one-half a first pointer clock cycle. The input data DIN at 30 is written into a memory in subsystem assembly 24 via the first pointer clock in the first clock domain. The data is read from the memory and provided as output data DOUT at 32 via the second pointer clock in the second clock domain. In one embodiment, the memory is a FIFO memory and input data DIN at 30 is sequentially written into the FIFO via the first pointer clock and data is read from the FIFO via the second pointer clock.

In one embodiment, the multiple clocks in the second clock domain include the second clock and a third clock that is 180 degrees out of phase with the second clock. Input circuit 28 samples the first clock via an edge of the second clock to obtain a phase relationship between the first clock and the second clock. Input circuit 28 selects the second clock or the third clock based on the sample, such that an edge of the selected clock relative to an edge of the first clock is within an uncertainty range of one-half the first clock cycle. Input circuit 28 provides a first pointer clock based on the first clock and a second pointer clock based on the selected clock, where the edge of the second pointer clock relative to the edge of the first pointer clock is limited to the uncertainty range of within one-half the first pointer clock cycle.

In one embodiment, the multiple clocks in the second clock domain include the second clock, a third clock that is 180 degrees out of phase with the second clock, a fourth clock that is 90 degrees out of phase with the second clock, and a fifth clock that is 270 degrees out of phase with the second clock. Input circuit 28 selects between the second clock, the third clock, the fourth clock, and the fifth clock, such that an edge of the selected clock relative to an edge of the first clock is limited to an uncertainty range of within one-fourth the first clock cycle. Input circuit 28 provides a first pointer clock based on the first clock and a second pointer clock based on the selected clock, where the edge of the second pointer clock relative to the edge of the first pointer clock is limited to the uncertainty range of within one-fourth the first pointer clock cycle.

In one embodiment, input data DIN at 30 is received via a clock and data recovery circuit that recovers the clock embedded in serial data and retimes the data to the recovered clock. The recovered clock is the first clock in the first clock domain. A clean clock, which is the second clock in the second clock domain, is obtained via the first clock and a phase locked loop (PLL). The second clock has substantially the same frequency as the first clock.

In one embodiment, input data DIN at 30 is received and a FIFO enable signal is clocked and latched in a clock pointer circuit via the first clock to provide a first enable signal that enables the first pointer clock. In one embodiment, input data DIN at 30 is received and a FIFO enable signal is clocked and latched in a clock pointer circuit via the first clock to provide a first enable signal that is clocked and latched in the clock pointer circuit via the selected clock to provide a second enable signal that enables the second pointer clock.

In one embodiment, input data DIN at 30 is received and a FIFO enable signal is clocked and latched in a clock pointer circuit via the first clock to provide a first enable signal. The first enable signal is latched in via the first clock to provide a latched enable signal. The latched enable signal is clocked and latched in the clock pointer circuit via the selected clock to provide a second enable signal that enables the second pointer clock.

In one embodiment, subsystem assembly 24 is an FB-DIMM that is one of multiple FB-DIMMs daisy-chained together and to host controller 22 via communications link 26. Each of the daisy-chained FB-DIMMs includes an AMB that provides a serial communications link. Each of the AMBs includes one or more input circuits 28 that receive input data DIN in one clock domain and provide output data DOUT in another clock domain.

Input circuit 28 limits the uncertainty range of the phase relationship between the second pointer clock and the first pointer clock to within one-half a full clock cycle. The reduced pointer uncertainty range decreases data latency through the FIFO and input circuit 28, which is critical to the operation of electronic systems in some applications, such as FB-DIMM applications.

FIG. 2 is a block diagram illustrating one embodiment of an FB-DIMM 40 that includes an AMB 42, first memory circuits 44a, and second memory circuits 44b. In one embodiment, the first memory circuits 44a include multiple DDR-DRAM circuits and the second memory circuits 44b include multiple DDR-DRAM circuits. In one embodiment, the first and second memory circuits 44a and 44b include 18 DDR-DRAM circuits. In other embodiments, FB-DIMM 40 includes any suitable type and number of memory circuits.

AMB 42 is electrically coupled to each of the first memory circuits 44a via first memory bus 46a and to each of the second memory circuits 44b via second memory bus 46b. In one embodiment, first memory bus 46a is a terminated communications bus and second memory bus 46b is a terminated communications bus. In one embodiment, first memory bus 46a is a fly-by communications bus and second memory bus 46b is a fly-by communications bus.

AMB 42 is electrically coupled to primary serial links 48 and secondary serial links 50. Primary serial links 48 electrically couple AMB 42 to a host controller, such as host controller 22, or an upper AMB. Secondary serial links 50 can be used to electrically couple AMB 42 to a lower AMB. Primary serial links 48 include primary southbound serial link 48a and primary northbound serial link 48b. Secondary serial links 50 include secondary southbound serial link 50a and secondary northbound serial link 50b.

Serial data from a host controller is sent through the primary southbound serial link 48a and received by AMB 42. The serial data from the host controller is temporarily buffered and then sent to first and second memory circuits 44a and 44b via first and second memory buses 46a and 46b. The serial data contains address, data, and command information. AMB 42 writes data into and reads data out of first and second memory circuits 44a and 44b as instructed by the host controller. The data read from the first and second memory circuits 44a and 44b is converted to serial data and sent back to the host controller via primary northbound serial link 48b.

AMB 42 receives serial data from the host controller or an upper AMB via primary southbound serial link 48a and transfers the serial data to a lower AMB via secondary southbound serial link 50a. Also, AMB 42 receives serial data from a lower AMB via secondary northbound serial link 50b. After merging the serial data with data of its own, AMB 42 sends the serial data to an upper AMB or the host controller via primary northbound serial link 48b. This forms a daisy-chain of FB-DIMMs.

AMB 42 includes primary input circuit 52a and secondary input circuit 52b. Primary input circuit 52a is electrically coupled to primary southbound serial link 48a and secondary input circuit 52b is electrically coupled to secondary northbound serial link 50b. Primary input circuit 52a receives input data DINA at 48a in a first clock domain from the host controller or an upper AMB. Primary input circuit 52a provides output data DOUTA at 54a in a second clock domain. Secondary input circuit 52b receives input data DINB at 50b in a first clock domain from a lower AMB and provides output data DOUTB at 54b in a second clock domain.

AMB 42 processes output data DOUTA at 54a. In one operation, input data DINA at 48a is serial data from a host controller and output data DOUTA at 54a is temporarily buffered and sent to first and second memory circuits 44a and 44b via first and second memory buses 46a and 46b. AMB 42 writes data into and reads data out of first and second memory circuits 44a and 44b as instructed by the host controller. The data read from the first and second memory circuits 44a and 44b is converted to serial data and sent back to the host controller via primary northbound serial link 48b. In another operation, input data DINA at 48a is serial data from a host controller or an upper AMB and output data DOUTA at 54a is transferred to a lower AMB via secondary southbound serial link 50a.

AMB 42 also processes output data DOUTB at 54b. AMB 42 receives input data DINB at 50b from a lower AMB via secondary northbound serial link 50b and merges output data DOUTB at 54b with data of its own. The serial data is sent to an upper AMB or the host controller via primary northbound serial link 48b.

Primary input circuit 52a is the same as secondary input circuit 52b. To avoid repetition, only primary input circuit 52a is described. Each of the input circuits 52a and 52b is similar to input circuit 28 (shown in FIG. 1).

Primary input circuit 52a receives input data DINA at 48a via a clock and data recovery circuit that recovers the clock embedded in input data DINA at 48a and retimes the data to the recovered clock. The recovered clock is the first clock in the first clock domain. A clean clock, which is the second clock in the second clock domain, is obtained via the first clock and a PLL. The second clock has substantially the same frequency as the first clock, but the phase relationship between the first clock and the second clock is unknown.

Primary input circuit 52a samples the first clock in the first clock domain via the second clock in the second clock domain to obtain the phase relationship between the first clock and the second clock. Based on the phase relationship between the first clock and the second clock, primary input circuit 52a selects one clock of multiple clocks in the second clock domain such that an edge of the selected clock relative to an edge of the first clock is limited to an uncertainty range of one-half a first clock cycle. In one embodiment, the multiple clocks in the second clock domain include the second clock and one or more clocks having different phase relationships to the second clock.

Primary input circuit 52a provides a first pointer clock based on the first clock and a second pointer clock based on the selected clock, where an edge of the second pointer clock relative to an edge of the first pointer clock is limited to the uncertainty range of within one-half a first pointer clock cycle. Input data DINA at 48a is written into a memory via the first pointer clock in the first clock domain. The data is read from the memory and provided as output data DOUTA at 54a via the second pointer clock in the second clock domain. In one embodiment, the memory is a FIFO memory and input data DINA at 48a is sequentially written into the FIFO via the first pointer clock and read from the FIFO via the second pointer clock.

In one embodiment, the multiple clocks in the second clock domain include the second clock and a third clock that is 180 degrees out of phase with the second clock. Primary input circuit 52a samples the first clock via an edge of the second clock to obtain a phase relationship between the first clock and the second clock. Primary input circuit 52a selects the second clock or the third clock based on the sample, such that an edge of the selected clock relative to an edge of the first clock is within an uncertainty range of one-half the first clock cycle. Primary input circuit 52a provides a first pointer clock based on the first clock and a second pointer clock based on the selected clock, where the edge of the second pointer clock relative to the edge of the first pointer clock is limited to the uncertainty range of one-half the first pointer clock cycle.

In one embodiment, the multiple clocks in the second clock domain include the second clock, a third clock that is 180 degrees out of phase with the second clock, a fourth clock that is 90 degrees out of phase with the second clock, and a fifth clock that is 270 degrees out of phase with the second clock. Primary input circuit 52a selects between the second clock, the third clock, the fourth clock, and the fifth clock, such that an edge of the selected clock relative to an edge of the first clock is limited to an uncertainty range of within one-fourth the first clock cycle. Primary input circuit 52a provides a first pointer clock based on the first clock and a second pointer clock based on the selected clock, where the edge of the second pointer clock relative to the edge of the first pointer clock is limited to the uncertainty range of within one-fourth the first pointer clock cycle.

In one embodiment, input data DINA at 48a is received and a FIFO enable signal is clocked and latched in a clock pointer circuit via the first clock to provide a first enable signal that enables the first pointer clock. In one embodiment, input data DINA at 48a is received and a FIFO enable signal is clocked and latched in a clock pointer circuit via the first clock to provide a first enable signal that is clocked and latched in the clock pointer circuit via the selected clock to provide a second enable signal that enables the second pointer clock.

In one embodiment, input data DINA at 48a is received and a FIFO enable signal is clocked and latched in a clock pointer circuit via the first clock to provide a first enable signal. The first enable signal is latched in via the first clock to provide a latched enable signal. The latched enable signal is clocked and latched in the clock pointer circuit via the selected clock to provide a second enable signal that enables the second pointer clock.

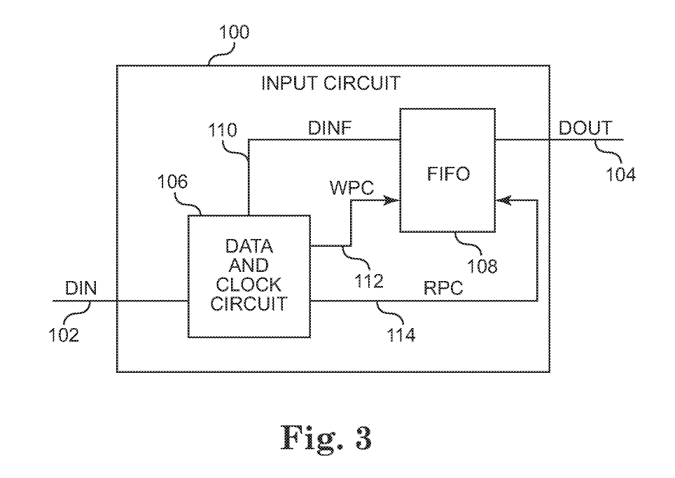

FIG. 3 is a diagram illustrating one embodiment of an input circuit 100 that receives input data DIN at 102 in a first clock domain and provides output data DOUT at 104 in a second clock domain. Input circuit 100 includes a data and clock circuit 106 and a FIFO memory 108. Data and clock circuit 106 is electrically coupled to FIFO 108 via data input path 110, write pointer clock path 112, and read pointer clock path 114. Input circuit 100 is similar to input circuit 28 (shown in FIG. 1) and to primary and secondary input circuits 52a and 52b (shown in FIG. 2).

Data and clock circuit 106 receives input data DIN at 102 and recovers the clock embedded in the serial input data DIN at 102. The recovered clock is the first clock in the first clock domain. Data and clock circuit 106 retimes input data DIN at 102 to the first clock and provides FIFO input data DINF at 110 to FIFO 108. Also, data and clock circuit 106 generates a clean clock, which is the second clock in the second clock domain, via the first clock and a PLL. The second clock has substantially the same frequency as the first clock.

Data and clock circuit 106 samples the first clock in the first clock domain via the second clock in the second clock domain and obtains the phase relationship between the first clock and the second clock. Based on the phase relationship between the first clock and the second clock, data and clock circuit 106 selects one clock of multiple clocks in the second clock domain such that an edge of the selected clock relative to an edge of the first clock is limited to an uncertainty range of one-half a first clock cycle. In one embodiment, the multiple clocks in the second clock domain include the second clock and one or more clocks having different phase relationships to the second clock.

Data and clock circuit 106 provides write pointer clock WPC at 112 based on the first clock, and read pointer clock RPC at 114 based on the selected clock. An edge of read pointer clock RPC at 114 relative to an edge of write pointer clock WPC at 112 is limited to the uncertainty range of within one-half a write pointer clock cycle. FIFO input data DINF at 110 is written into FIFO 108 via write pointer clock WPC at 112 in the first clock domain. Data is read from FIFO 108 and provided in output data DOUT at 104 via read pointer clock RPC at 114 in the second clock domain. In one embodiment, FIFO input data DINF at 110 is sequentially written into FIFO 108 via write pointer clock WPC at 112 and read from FIFO 108 via read pointer clock RPC at 114.

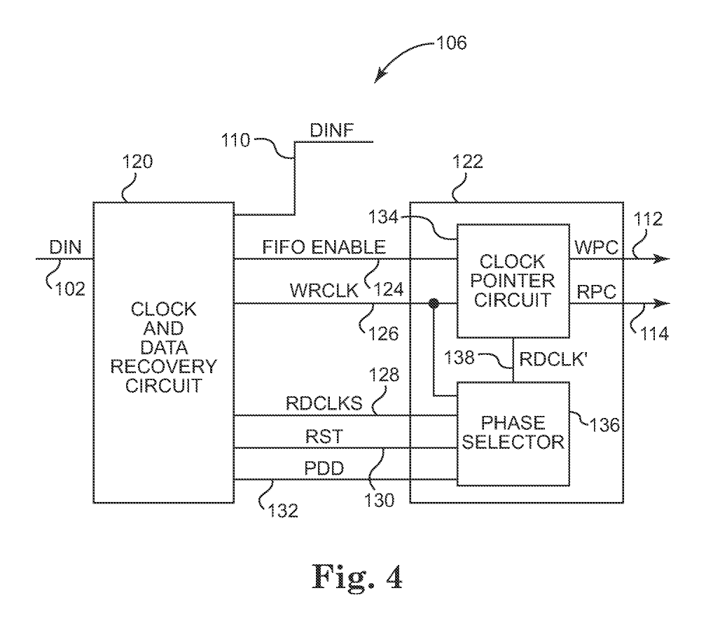

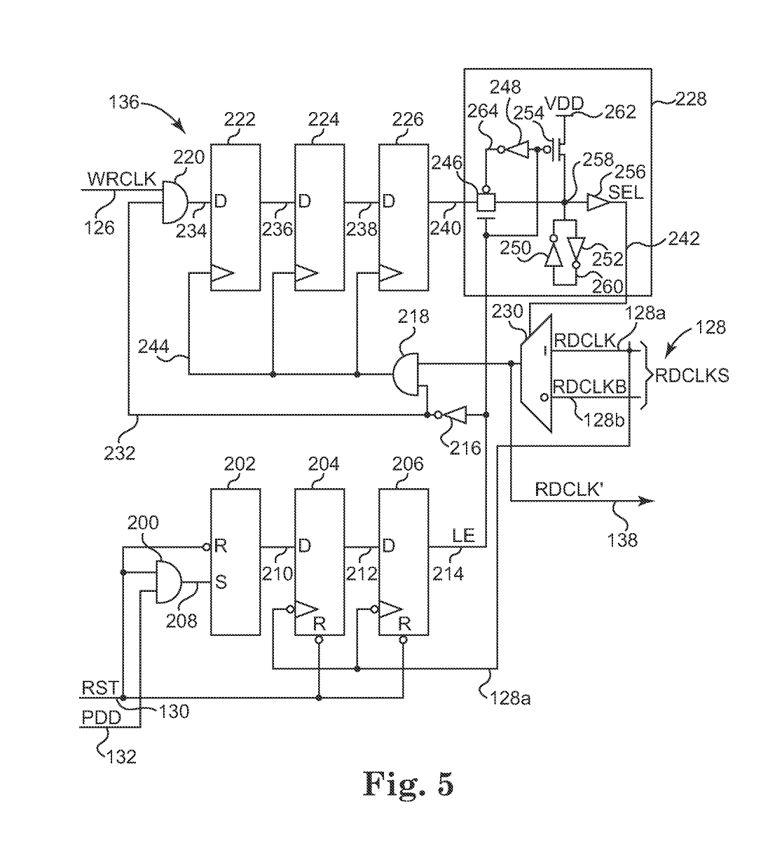

FIG. 4 is a diagram illustrating one embodiment of a data and clock circuit 106 that receives input data DIN at 102 and provides FIFO input data DINF at 110, write pointer clock WPC at 112, and read pointer clock RPC at 114. Input data DIN at 102, FIFO input data DINF at 110, and write pointer clock WPC at 112 are in the first clock domain. Read pointer clock RPC at 114 is in the second clock domain.

Data and clock circuit 106 includes a clock and data recovery circuit 120 and a phase and clock pointer circuit 122. Clock and data recovery circuit 120 is electrically coupled to phase and clock pointer circuit 122 via enable signal path 124, write clock path 126, read clock path 128, reset path 130, and phase detection path 132. Phase and clock pointer circuit 122 includes a clock pointer circuit 134 and a phase selector 136. Clock and data recovery circuit 120 is electrically coupled to clock pointer circuit 134 via enable signal path 124 and write clock path 126. Clock and data recovery circuit 120 is electrically coupled to phase selector 136 via write clock path 126, read clock path 128, reset path 130, and phase detection path 132. Clock pointer circuit 134 is electrically coupled to phase selector 136 via selected read clock path 138.

Clock and data recovery circuit 120 receives input data DIN at 102 and provides an active FIFO enable signal FIFO ENABLE at 124 that indicates data is being received or will be received. Clock and data recovery circuit 120 recovers the clock embedded in the serial input data DIN at 102. The recovered clock is the first clock in the first clock domain, referred to herein as write clock WRCLK at 126. Clock and data recovery circuit 120 retimes input data DIN at 102 via write clock WRCLK at 126 and provides the retimed data as FIFO input data DINF at 110. Clock and data recovery circuit 120 generates multiple clocks in the second clock domain, including the second clock, via write clock WRCLK at 126 and a PLL. The multiple clocks are provided as read clocks RDCLKS at 128. Each of the read clocks RDCLKS at 128 has substantially the same frequency as write clock WRCLK at 126, but a different phase relationship to write clock WRCLK at 126. In other embodiments, read clocks RDCLKS at 128 can be generated in a circuit other than clock and data recovery circuit 120.

Phase selector 136 receives read clocks RDCLKS at 128, a reset signal RST at 130, and a phase detection done signal PDD at 132. Clock and data recovery circuit 120 provides an active reset signal RST at 130 to reset phase selector 136 for finding a phase relationship between write clock WRCLK at 126 and read clocks RDCLKS at 128. Phase selector 136 samples write clock WRCLK at 126 in the first clock domain via read clocks RDCLKS at 128 in the second clock domain to obtain the phase relationship between write clock WRCLK at 126 and read clocks RDCLKS at 128. Clock and data recovery circuit 120 provides an active phase detection done signal PDD at 132 to end the sampling period. Based on the phase relationship between write clock WRCLK at 126 and read clocks RDCLKS at 128, phase selector 136 selects one of the read clocks RDCLKS at 128 in the second clock domain and provides the selected read clock RDCLK′ at 138. An edge of the selected read clock RDCLK′ at 138 relative to an edge of write clock WRCLK at 126 is limited to an uncertainty range of one-half a write clock cycle of write clock WRCLK at 126. In one embodiment, reset signal RST at 130 is pulsed active. In one embodiment, reset signal RST at 130 is held active as phase selector 136 samples write clock WRCLK at 126 via the read clocks RDCLKS at 128. In other embodiments, another circuit such as a control circuit provides reset signal RST at 130 and phase detection done signal PDD at 132.

Clock pointer circuit 134 receives FIFO enable signal FIFO ENABLE at 124, write clock WRCLK at 126, and the selected read clock RDCLK′ at 138. Clock pointer circuit 134 provides write pointer clock WPC at 112 based on write clock WRCLK at 126 and read pointer clock RPC at 114 based on the selected read clock RDCLK′ at 138. An edge of read pointer clock RPC at 114 relative to an edge of write pointer clock WPC at 112 is limited to the uncertainty range of within one-half a clock cycle of write pointer clock WPC at 112. FIFO input data DINF at 110 is sequentially written into a FIFO via write pointer clock WPC at 112 and read from the FIFO via read pointer clock RPC at 114.

In one embodiment, FIFO enable signal FIFO ENABLE at 124 is clocked and latched into clock pointer circuit 134 via write clock WRCLK at 126 to provide a first enable signal that enables write pointer clock WPC at 112. In one embodiment, FIFO enable signal FIFO ENABLE at 124 is clocked and latched into clock pointer circuit 134 via write clock WRCLK at 126 to provide a first enable signal that is clocked and latched into clock pointer circuit 134 via selected read clock RDCLK′ at 138 to provide a second enable signal that enables read pointer clock RPC at 114.

In one embodiment, FIFO enable signal FIFO ENABLE at 124 is clocked and latched into clock pointer circuit 134 via write clock WRCLK at 126 to provide a first enable signal. The first enable signal is latched in via write clock WRCLK at 126 to provide a latched enable signal and the latched enable signal is clocked and latched in clock pointer circuit 134 via selected read clock RDCLK′ at 138 to provide a second enable signal that enables read pointer clock RPC at 114.

In one embodiment, read clocks RDCLKS at 128 in the second clock domain include the second clock and a third clock that is 180 degrees out of phase with the second clock. Phase selector 136 samples write clock WRCLK at 126 via one or more of the read clocks RDCLKS at 128 to obtain a phase relationship between write clock WRCLK at 126 and read clocks RDCLKS at 128. Phase selector 136 selects the second clock or the third clock based on the sample, such that an edge of the selected read clock RDCLK′ at 138 relative to an edge of write clock WRCLK at 126 is within an uncertainty range of one-half a clock cycle of write clock WRCLK at 126. Clock pointer circuit 134 provides write pointer clock WPC at 112 based on write clock WRCLK at 126 and read pointer clock RPC at 114 based on the selected read clock RDCLK′ at 138, where the edge of read pointer clock RPC at 114 relative to the edge of write pointer clock WPC at 112 is limited to the uncertainty range of one-half the clock cycle of write pointer clock WPC at 112.

In one embodiment, read clocks RDCLKS at 128 in the second clock domain include the second clock, a third clock that is 180 degrees out of phase with the second clock, a fourth clock that is 90 degrees out of phase with the second clock, and a fifth clock that is 270 degrees out of phase with the second clock. Phase selector 136 samples write clock WRCLK at 126 via one or more of the read clocks RDCLKS at 128 to obtain a phase relationship between write clock WRCLK at 126 and read clocks RDCLKS at 128. Phase selector 136 selects between the second clock, the third clock, the fourth clock, and the fifth clock, such that an edge of the selected read clock RDCLK′ at 138 relative to an edge of write clock WRCLK at 126 is limited to an uncertainty range of within one-fourth a clock cycle of write clock WRCLK at 126. Clock pointer circuit 134 provides write pointer clock WPC at 112 based on write clock WRCLK at 126 and read pointer clock RPC at 114 based on the selected read clock RDCLK′ at 138, where the edge of read pointer clock RPC at 114 relative to the edge of write pointer clock WPC at 112 is limited to the uncertainty range of within one-fourth the clock cycle of write pointer clock WPC at 112.

FIG. 5 is a diagram illustrating one embodiment of a phase selector 136 that receives write clock WRCLK at 126, read clocks RDCLKS at 128, reset signal RST at 130, and phase detection done signal PDD at 132. Read clocks RDCLKS at 128 include read clock RDCLK at 128a and inverted read clock RDCLKB at 128b, which is 180 degrees out of phase with read clock RDCLK at 128a. Phase selector 136 selects one of the read clocks RDCLKS at 128 and provides the selected read clock RDCLK′ at 138.

Phase selector 136 includes a first AND gate 200, an SR latch 202, a first flip-flop 204, and a second flip-flop 206. The output of first AND gate 200 is electrically coupled to the active high set input S of SR latch 202 via set input path 208. The output of SR latch 202 is electrically coupled to the data input D of first flip-flop 204 via first data input path 2 10. The output of first flip-flop 204 is electrically coupled to the data input D of second flip-flop 206 via second data input path 212.

The active low reset input R of SR latch 202 and one input of first AND gate 200 receives reset signal RST at 130. The other input of first AND gate 200 receives phase detection done signal PDD at 132. Also, the active low reset input R of first flip-flop 204 and the active low reset input R of second flip-flop 206 receive reset signal RST at 130. The falling edge triggered clock input of first flip-flop 204 and the falling edge triggered clock input of second flip-flop 206 receive read clock RDCLK at 128a. Second flip-flop 206 provides a latch enable signal LE via latch enable path 214.

Phase selector 136 also includes a first inverter 216, a second AND gate 218, a third AND gate 220, a third flip-flop 222, a fourth flip-flop 224, a fifth flip-flop 226, a latch 228, and a multiplexer 230. The output of second flip-flop 206 is electrically coupled to latch 228 and the input of first inverter 216 via latch enable path 214. The output of first inverter 216 is electrically coupled to one input of second AND gate 218 and one input of third AND gate 220 via input path 232.

The other input of third AND gate 220 receives write clock WRCLK at 126 and the output of third AND gate 220 is electrically coupled to the data input D of third flip-flop 222 via third data input path 234. The output of third flip-flop 222 is electrically coupled to the data input D of fourth flip-flop 224 via fourth data input path 236. The output of fourth flip-flop 224 is electrically coupled to the data input D of fifth flip-flop 226 via fifth data input path 23 8. The output of fifth flip-flop 226 is electrically coupled to latch 228 via transmission path 240.

Multiplexer 230 receives read clock RDCLK at 128a, inverted read clock RDCLKB at 128b, and a select signal SEL via select input path 242. Multiplexer 230 selects either read clock RDCLK at 128a or inverted read clock RDCLKB at 128b and provides the selected read clock RDCLK′ at 138 to clock pointer circuit 134 (shown in FIG. 4) and the other input of second AND gate 218. The output of second AND gate 218 is electrically coupled to the positive edge triggered clock inputs of third flip-flop 222, fourth flip-flop 224, and fifth flip-flop 226 via clock input path 244.

Latch 228 includes a transmission gate 246, a second inverter 248, a third inverter 250, a fourth inverter 252, a p-channel metal oxide semiconductor (PMOS) transistor 254, and a non-inverting buffer 256. One side of the transmission gate 246 is electrically coupled to the output of fifth flip-flop 226 via transmission path 240. The other side of transmission gate 246 is electrically coupled to the output of third inverter 250, the input of fourth inverter 252, one side of the drain-source path of PMOS transistor 254, and the input of buffer 256 via sample path 258. Third and fourth inverters 250 and 252 are electrically coupled in an inverter latch to latch the sample on sample path 258, where the input of third inverter 250 is electrically coupled to the output of fourth inverter 252 via inverter output path 260. The other side of the drain-source path of PMOS transistor 254 is electrically coupled to power supply VDD at 262.

The gate of PMOS transistor 254, an active high input of transmission gate 246, and the input of second inverter 248 are electrically coupled to the output of second flip-flop 206 via latch enable path 214. The output of second inverter 248 is electrically coupled to the active low input of transmission gate 246 via second inverter path 264. Also, the output of buffer 256 is electrically coupled to the select input of multiplexer 230 via select input path 242.

In operation, a circuit, such as clock and data recovery circuit 120, provides a low level reset signal RST at 130 and a low level phase detection done signal PDD at 132, which resets SR latch 202, first flip-flop 204, and second flip-flop 206. SR latch 202 provides a low level output at 210, first flip-flop 204 provides a low level output at 212, and second flip-flop 206 provides a low level latch enable signal LE at 214. In one embodiment, reset signal RST at 130 is pulsed low. In other embodiments, reset signal RST at 130 is held low while sampling write clock WRCLK at 126.

In response to the low level latch enable signal LE at 214, transmission gate 246 is switched off to not conduct and PMOS transistor 254 is switched on to conduct. The conducting PMOS transistor 254 pulls sample path 258 to a high level and buffer 256 provides a high level select signal SEL at 242. Multiplexer 230 receives the high level select signal SEL at 242 and selects read clock RDCLK at 128a. The selected read clock RDCLK′ at 138 is received by second AND gate 218. Also, first inverter 216 receives the low level latch enable signal LE at 214 and provides a high level signal to second AND gate 218 and third AND gate 220.

Write clock WRCLK at 126 is sampled via the positive edge of read clock RDCLK at 128a to obtain the phase relationship between write clock WRCLK at 126 and read clock RDCLK at 128a. Write clock WRCLK at 126 is received by third AND gate 220 and provided to the data input D of third flip-flop 222. The selected read clock RDCLK′ at 138, which is read clock RDCLK at 128a, is received by second AND gate 218 and provided to the positive edge triggered clock inputs of third flip-flop 222, fourth flip-flop 224, and fifth flip-flop 226. Write clock WRCLK at 126 is provided to the data input D of third flip-flop 222 via third AND gate 220 and sampled by third flip-flop 222 at the positive edge of the selected read clock RDCLK′ at 138, which is provided to the positive edge triggered clock input of third flip-flop 222 via second AND gate 218. On subsequent positive edges of read clock RDCLK at 128a and selected read clock RDCLK′ at 138, third flip-flop 222, fourth flip-flop 224 and fifth flip-flop 226 clock in samples of write clock WRCLK at 126 and fifth flip-flop 226 provides the samples at 240. Since transmission gate 246 is switched off, the samples do not propagate through transmission gate 246.

To cease the sampling of write clock WRCLK at 126, the circuit provides a high level reset signal RST at 130 and a high level phase detection done signal PDD at 132. First AND gate 200 transitions to a high level and SR latch 202 is set to provide a high level output at 210. First flip-flop 204 receives the high level output at 210 and the next falling edge of read clock RDCLK at 128a clocks the high level output at 210 into first flip-flop 204. First flip-flop 204 provides the high level output at 212 and the next falling edge of read clock RDCLK at 128a clocks the high level output at 212 into second flip-flop 206. Second flip-flop 206 provides a high level latch enable signal LE at 214.

In response to the high level latch enable signal LE at 214, first inverter 216 provides a low level to second AND gate 218 and third AND gate 220, which provide low level signals to the data input D of third flip-flop 222 and the positive edge triggered clock inputs of third flip-flop 222, fourth flip-flop 224 and fifth flip-flop 226. This stops the sampling of write clock WRCLK at 126. Since first and second flip-flops 204 and 206 clock in the high level signals on the falling edge of read clock RDCLK at 128a, the gated clock output of second AND gate 218 is disabled at the time the clock signal is at a low level. This prevents small pulses, referred to as runt pulses, which can adversely affect the operation of third flip-flop 222, fourth flip-flop 224, and fifth flip-flop 226.

Also, in response to the high level latch enable signal LE at 214, transmission gate 246 is switched on to conduct the sample at 240 of write clock WRCLK at 126. The conducted sample at 258 is latched in via the inverter latch that includes third and fourth inverters 250 and 252. Buffer 256 provides the latched sample at 258 in select input signal SEL at 242 to multiplexer 230.

Multiplexer 230 selects either read clock RDCLK at 128a or inverted read clock RDCLKB at 128b and provides the selected read clock RDCLK′ at 138. If the sample in select input signal SEL at 242 is at a high level, multiplexer 230 provides read clock RDCLK at 128a as selected read clock RDCLK′ at 138 and the positive edge of read clock RDCLK at 128a is in the 180 degree high phase portion of write clock WRCLK at 126. If the sample in select input signal SEL at 242 is at a low level, multiplexer 230 provides inverted read clock RDCLKB at 128b as the selected read clock RDCLK′ at 138 and the positive edge of inverted read clock RDCLKB at 128b is in the 180 degree high phase of write clock WRCLK at 126. Thus, the rising edge of the selected read clock RDCLK′ at 138 relative to the rising edge of write clock WRCLK at 126 is limited to a uncertainty range of within one-half a clock cycle of the write clock WRCLK at 126.

In another embodiment of phase selector 136, the read clocks RDCLKS at 128 include a read clock RDCLK, an inverted read clock RDCLKB that is 180 degrees out of phase with read clock RDCLK, a read clock RDCLK90 that is 90 degrees out of phase with read clock RDCLK, and a read clock RDCLK270 that is 270 degrees out of phase with read clock RDCLK. Phase selector 136 samples write clock WRCLK at 126 via two or more of the read clocks RDCLKS at 128 to obtain the phase relationship between write clock WRCLK at 126 and the read clocks RDCLKS at 128. Phase selector 136 selects one of the read clocks RDCLKS at 128 such that one edge of the selected read clock RDCLK′ at 138 relative to one edge of write clock WRCLK at 126 is limited to an uncertainty range of within one-fourth a clock cycle of write clock WRCLK at 126.

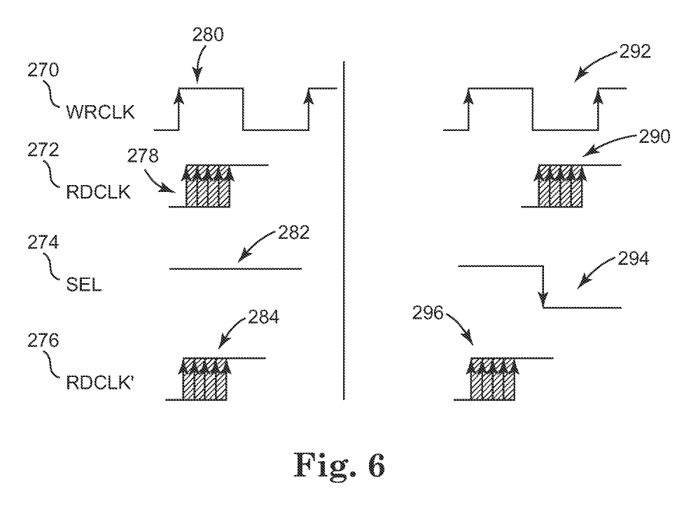

FIG. 6 is a timing diagram illustrating the operation of phase selector 136 of FIG. 5. Write clock WRCLK at 270 is provided to third AND gate 220 and sampled via read clock RDCLK at 272. Latch 228 provides select signal SEL at 274 based on the sample of write clock WRCLK at 270. Multiplexer 230 receives read clock RDCLK at 272, an inverted read clock RDCLKB, and select signal SEL at 274. Multiplexer 230 selects either read clock RDCLK at 272 or the inverted read clock RDCLKB based on select signal SEL at 274. Multiplexer 230 provides the selected clock signal as selected read clock RDCLK′ at 276.

In one example, read clock RDCLK at 272 includes rising edges at 278 in the high level phase at 280 of write clock WRCLK at 270. Read clock RDCLK at 272 is used to sample a high level in write clock WRCLK at 270 via the rising edges at 278. Latch 228 provides a high level at 282 in select signal SEL at 274 based on the high level sample. Multiplexer 230 receives the high level select signal SEL at 274 and selects read clock RDCLK at 272. Multiplexer 230 provides read clock RDCLK at 272 as the selected clock at 284 in read clock RDCLK′ at 276.

In another example, read clock RDCLK at 272 includes rising edges at 290 in the low level phase at 292 of write clock WRCLK at 270. Read clock RDCLK at 272 is used to sample a low level of write clock WRCLK at 270 via the rising edges at 290. Latch 228 transitions select signal SEL at 274 to provide a low level at 294 in select signal SEL at 274 based on the low level sample. Multiplexer 230 receives the low level select signal SEL at 274 and selects inverted read clock RDCLKB. Multiplexer 230 provides inverted read clock RDCLKB as the selected clock at 296 in read clock RDCLK′ at 276.

Phase selector 136 selects either read clock RDCLK at 272 or RDCLKB, such that the rising edge of the selected read clock RDCLK′ at 276 is restricted to the high level phase of write clock WRCLK at 270. The rising edge of the selected read clock RDCLK′ at 276 relative to the rising edge of write clock WRCLK at 270 is limited to an uncertainty range of within one-half a clock cycle of write clock WRCLK at 270. In other embodiments of phase selector 136, phase selector 136 selects either read clock RDCLK at 272 or RDCLKB, such that the rising edge of the selected read clock RDCLK′ at 276 is restricted to the low level phase of write clock WRCLK at 270. The rising edge of the selected read clock RDCLK′ at 276 relative to the falling edge of write clock WRCLK at 270 is limited to an uncertainty range of within one-half a clock cycle of write clock WRCLK at 270.

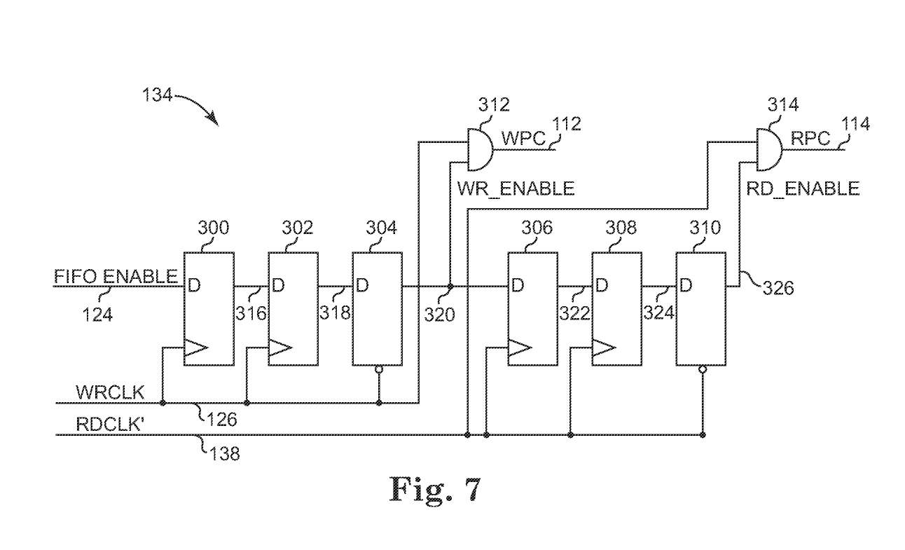

FIG. 7 is a diagram illustrating one embodiment of a clock pointer circuit 134. Clock pointer circuit 134 receives FIFO enable signal FIFO ENABLE at 124, write clock WRCLK at 126, and the selected read clock RDCLK′ at 138 and provides write pointer clock WPC at 112 and read pointer clock RPC at 114. Clock pointer circuit 134 receives FIFO enable signal FIFO ENABLE at 124 and write clock WRCLK at 126 from a circuit, such as clock and data recovery circuit 120. Clock pointer circuit 134 receives the selected read clock RDCLK′ at 138 from a circuit, such as phase selector 136.

Clock pointer circuit 134 includes first flip-flop 300, second flip-flop 302, write enable latch 304, third flip-flop 306, fourth flip-flop 308, read enable latch 310, write pointer AND gate 312, and read pointer AND gate 314. The output of first flip-flop 300 is electrically coupled to the data input D of second flip-flop 302 via first data path 316. The output of second flip-flop 302 is electrically coupled to the data input D of write enable latch 304 via second data path 318. The output of write enable latch 304 is electrically coupled to the data input D of third flip-flop 306 and to one input of write pointer AND gate 312 via third data path 320. The output of third flip-flop 306 is electrically coupled to the data input D of fourth flip-flop 308 via fourth data path 322. The output of fourth flip-flop 308 is electrically coupled to the data input D of read enable latch 310 via fifth data path 324. The output of read enable latch 310 is electrically coupled to one input of read pointer AND gate 314 via sixth data path 326.

The data input D of first flip-flop 300 receives FIFO enable signal FIFO ENABLE at 124 and the positive edge triggered clock input of first flip-flop 300 receives write clock WRCLK at 126. Also, the positive edge triggered clock input of second flip-flop 302, the active low latch input of write enable latch 304, and an input of write pointer AND gate 312 receive write clock WRCLK at 126. The positive edge triggered clock input of third flip-flop 306 and the positive edge triggered clock input of fourth flip-flop 308 receive the selected read clock RDCLK′ at 138. In addition, the active low latch input of read enable latch 310 and an input of read pointer AND gate 314 receives the selected read clock RDCLK′ at 138.

In operation, clock and data recovery circuit 120 receives input data DIN at 102 and provides a high level FIFO enable signal FIFO ENABLE at 124 that indicates data is being received or will be received. First flip-flop 300 receives the high level FIFO enable signal FIFO ENABLE at 124 and the next positive edge of write clock WRCLK at 126 clocks the high level FIFO enable signal FIFO ENABLE at 124 into first flip-flop 300. Second flip-flop 302 receives the clocked in high level FIFO enable signal at 316 and the next positive edge of write clock WRCLK at 126 clocks the high level FIFO enable signal at 316 into second flip-flop 302. Write enable latch 304 receives the clocked in high level FIFO enable signal at 318 and at the next falling edge and low level of write clock WRCLK at 126, write enable latch 304 provides a high level write enable signal WR_ENABLE at 320.

Write enable AND gate 312 receives write clock WRCLK at 126 and the high level write enable signal WR_ENABLE at 320 that enables write enable AND gate 312 to provide write pointer clock WPC at 112.

Third flip-flop 306 receives the high level write enable signal WR_ENABLE at 320 and the next positive edge of the selected read clock RDCLK′ at 138 clocks the high level write enable signal WR_ENABLE at 320 into third flip-flop 306. Fourth flip-flop 308 receives the clocked in high level write enable signal at 322 and the next positive edge of the selected read clock RDCLK′ at 138 clocks the high level write enable signal at 322 into fourth flip-flop 308. Read enable latch 310 receives the clocked in high level write enable signal at 324 and at the next falling edge and low level of the selected read clock RDCLK′ at 138, read enable latch 310 provides a high level read enable signal RD_ENABLE at 326.

Read enable AND gate 314 receives the selected read clock RDCLK′ at 138 and the high level read enable signal RD_ENABLE at 326 that enables read enable AND gate 314 to provide read pointer clock RPC at 114.

In one embodiment, phase selector 136 selects one of the read clock RDCLKS such that the rising edge of the selected read clock RDCLK′ at 138 is restricted to the high level phase of write clock WRCLK at 126 and clock pointer circuit 134 provides the rising edge of the read pointer clock RPC at 114 restricted to the high level phase of write pointer clock WPC at 112.

In one embodiment, the rising edge of the selected read clock RDCLK′ at 138 relative to the rising edge of write clock WRCLK at 126 is limited to an uncertainty range of within one-half a clock cycle of write clock WRCLK at 126 and the rising edge of read pointer clock RPC at 114 relative to the rising edge of write pointer clock WPC at 112 is limited to the uncertainty range of within one-half a clock cycle of write pointer clock WPC at 112.

In one embodiment, the rising edge of the selected read clock RDCLK′ at 138 relative to the rising edge of write clock WRCLK at 126 is limited to an uncertainty range of within one-fourth a clock cycle of write clock WRCLK at 126 and the rising edge of read pointer clock RPC at 114 relative to the rising edge of write pointer clock WPC at 112 is limited to the uncertainty range of within one-fourth a clock cycle of write pointer clock WPC at 112.

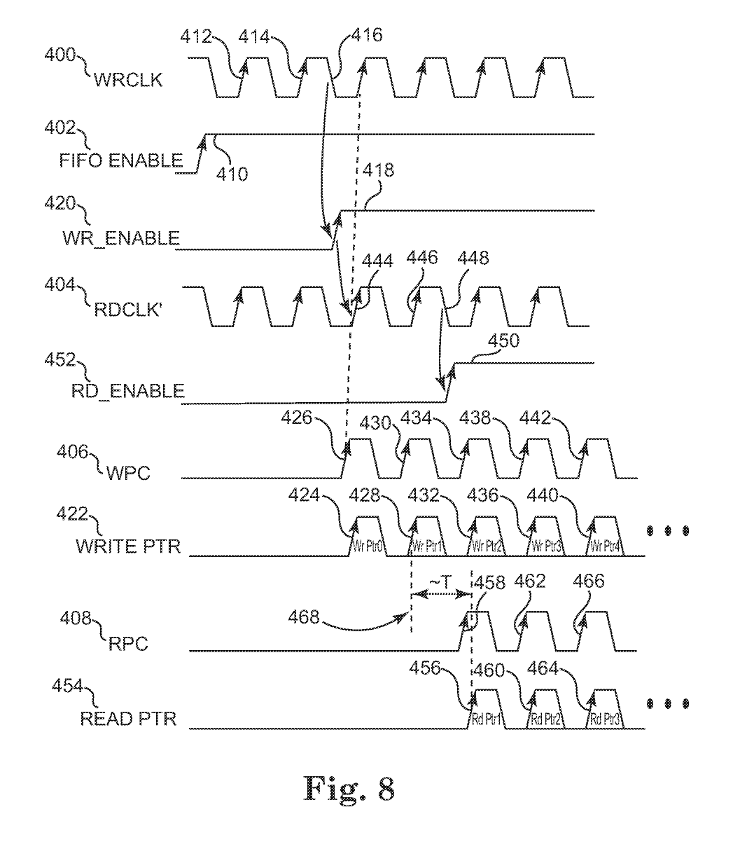

FIG. 8 is a timing diagram illustrating the operation of clock pointer circuit 134, where the resulting spacing between write pointers and read pointers is one clock period T of write pointer clock WPC. Clock pointer circuit 134 receives write clock WRCLK at 400, FIFO enable signal FIFO ENABLE at 402, and the selected read clock RDCLK′ at 404 and provides write pointer clock WPC at 406 and read pointer clock RPC at 408. In this example, write clock WRCLK at 400 and the selected read clock RDCLK′ at 404 are nearly edge aligned.

Clock and data recovery circuit 120 receives input data DIN at 102 and provides a high level at 410 in FIFO enable signal FIFO ENABLE at 402 that indicates data is being received or will be received. First flip-flop 300 receives the high level at 410 in FIFO enable signal FIFO ENABLE at 402 and the next positive edge at 412 of write clock WRCLK at 400 clocks the high level at 410 into first flip-flop 300. Second flip-flop 302 receives the clocked in high level and the next positive edge at 414 of write clock WRCLK at 400 clocks the high level into second flip-flop 302. Write enable latch 304 receives the clocked in high level and at the next falling edge and low level at 416 of write clock WRCLK at 400, write enable latch 304 provides a high level at 418 of write enable signal WR_ENABLE at 420. Write enable AND gate 312 receives write clock WRCLK at 400 and the high level at 418 of write enable signal WR_ENABLE at 420 and provides write pointer clock WPC at 406.

Write pointer clock WPC at 406 is used to provide write pointers WRITE PTR at 422, where write pointer 0 at 424 is based on the rising edge at 426, write pointer 1 at 428 is based on the rising edge at 430, write pointer 2 at 432 is based on the rising edge at 434, write pointer 3 at 436 is based on the rising edge at 438, write pointer 4 at 440 is based on the rising edge at 442, and so on, up to the pointer limit at which point the write pointers WRITE PTR at 422 begin again with write pointer 0.

Third flip-flop 306 receives the high level at 418 of write enable signal WR_ENABLE at 420 and the next positive edge at 444 of the selected read clock RDCLK′ at 404 clocks the high level at 418 of write enable signal WR_ENABLE at 420 into third flip-flop 306. Fourth flip-flop 308 receives the clocked in high level and the next positive edge at 446 of the selected read clock RDCLK′ at 404 clocks the high level into fourth flip-flop 308. Read enable latch 310 receives the clocked in high level and at the next falling edge and low level at 448 of the selected read clock RDCLK′ at 404, read enable latch 310 provides a high level at 450 of read enable signal RD_ENABLE at 452. Read enable AND gate 314 receives the selected read clock RDCLK′ at 404 and the high level at 450 of read enable signal RD_ENABLE at 452 and provides read pointer clock RPC at 408.

Read pointer clock RPC at 408 is used to provide read pointers READ PTR at 454, where read pointer 1 at 456 is based on the rising edge at 458, read pointer 2 at 460 is based on the rising edge at 462, read pointer 3 at 464 is based on the rising edge at 466, and so on, up to the pointer limit at which point the read pointers READ PTR at 454 begin again with read pointer 0.

The resulting spacing between write pointers WRITE PTR at 422 and read pointers READ PTR at 454 is about one clock period T of write pointer clock WPC at 406, indicated at 468.

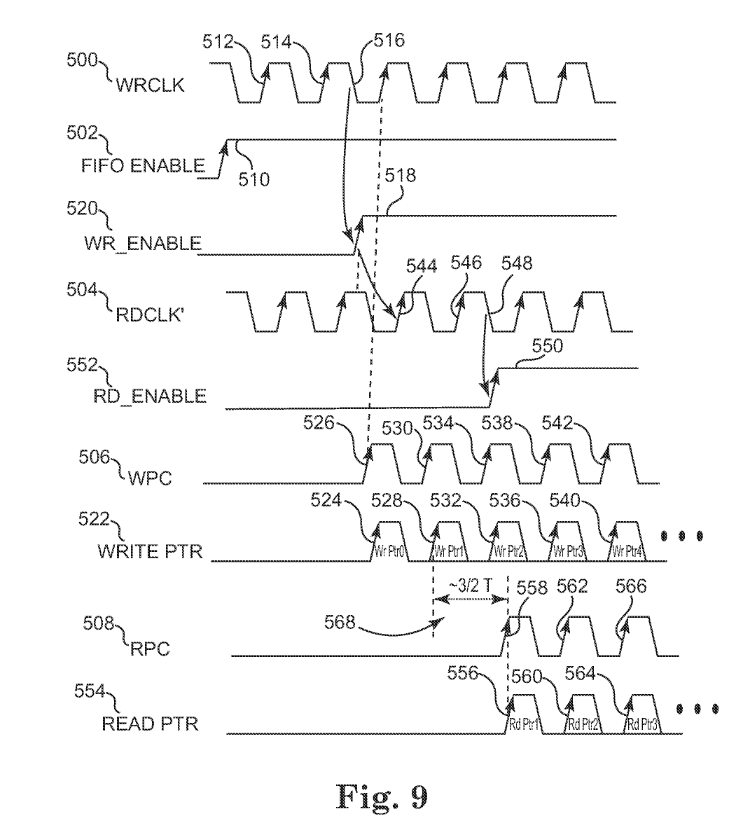

FIG. 9 is a timing diagram illustrating the operation of clock pointer circuit 134, where the resulting spacing between write pointers and read pointers is one and a half clock periods (3/2 T) of write pointer clock WPC. Clock pointer circuit 134 receives write clock WRCLK at 500, FIFO enable signal FIFO ENABLE at 502, and the selected read clock RDCLK′ at 504 and provides write pointer clock WPC at 506 and read pointer clock RPC at 508. In this example, write clock WRCLK at 500 and the selected read clock RDCLK′ at 504 are nearly anti-phase or about one half clock cycle out of edge alignment.

Clock and data recovery circuit 120 receives input data DIN at 102 and provides a high level at 510 in FIFO enable signal FIFO ENABLE at 502 that indicates data is being received or will be received. First flip-flop 300 receives the high level at 510 in FIFO enable signal FIFO ENABLE at 502 and the next positive edge at 512 of write clock WRCLK at 500 clocks the high level at 510 into first flip-flop 300. Second flip-flop 302 receives the clocked in high level and the next positive edge at 514 of write clock WRCLK at 500 clocks the high level into second flip-flop 302. Write enable latch 304 receives the clocked in high level and at the next falling edge and low level at 516 of write clock WRCLK at 500, write enable latch 304 provides a high level at 518 of write enable signal WR_ENABLE at 520. Write enable AND gate 312 receives write clock WRCLK at 500 and the high level at 518 of write enable signal WR_ENABLE at 520 and provides write pointer clock WPC at 506.

Write pointer clock WPC at 506 is used to provide write pointers WRITE PTR at 522, where write pointer 0 at 524 is based on the rising edge at 526, write pointer 1 at 528 is based on the rising edge at 530, write pointer 2 at 532 is based on the rising edge at 534, write pointer 3 at 536 is based on the rising edge at 538, write pointer 4 at 540 is based on the rising edge at 542, and so on, up to the pointer limit at which point the write pointers WRITE PTR at 522 begin again with write pointer 0.

Third flip-flop 306 receives the high level at 518 of write enable signal WR_ENABLE at 520 and the next positive edge at 544 of the selected read clock RDCLK′ at 504 clocks the high level at 518 of write enable signal WR_ENABLE at 520 into third flip-flop 306. Fourth flip-flop 308 receives the clocked in high level and the next positive edge at 546 of the selected read clock RDCLK′ at 504 clocks the high level into fourth flip-flop 308. Read enable latch 310 receives the clocked in high level and at the next falling edge and low level at 548 of the selected read clock RDCLK′ at 504, read enable latch 310 provides a high level at 550 of read enable signal RD_ENABLE at 552. Read enable AND gate 314 receives the selected read clock RDCLK′ at 504 and the high level at 550 of read enable signal RD_ENABLE at 552 and provides read pointer clock RPC at 508.

Read pointer clock RPC at 508 is used to provide read pointers READ PTR at 554, where read pointer 1 at 556 is based on the rising edge at 558, read pointer 2 at 560 is based on the rising edge at 562, read pointer 3 at 564 is based on the rising edge at 566, and so on, up to the pointer limit at which point the read pointers READ PTR at 554 begin again with read pointer 0.

The resulting spacing between write pointers WRITE PTR at 522 and read pointers READ PTR at 554 is about one and a half clock periods (3/2 T) of write pointer clock WPC at 506, indicated at 568.

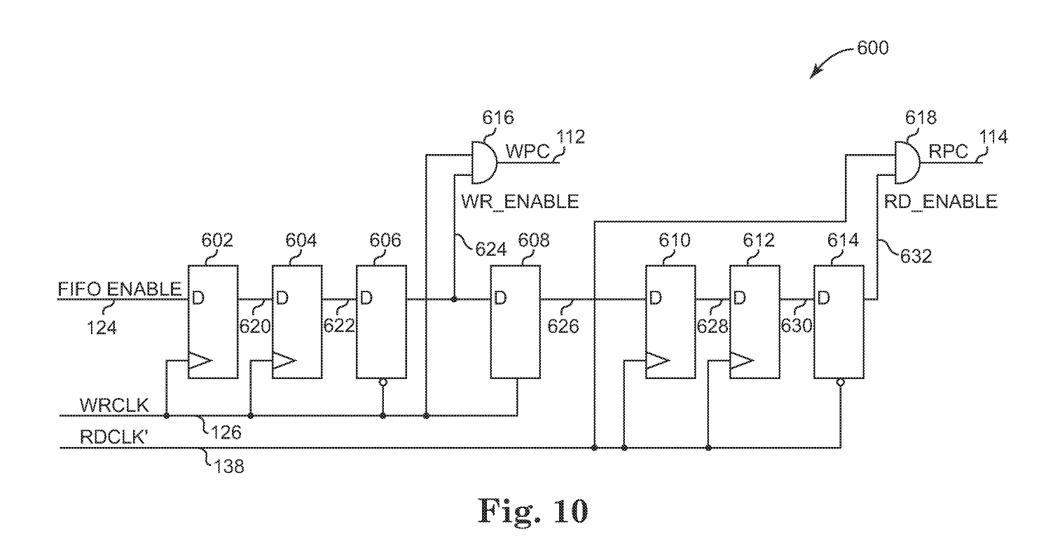

FIG. 10 is a diagram illustrating one embodiment of a clock pointer circuit 600 that is used to provide write pointer clock WPC at 112 and read pointer clock RPC at 114 if the rising edge of the selected read clock RDCLK′ at 138 is restricted to the low level phase of write clock WRCLK at 126. Clock pointer circuit 600 receives FIFO enable signal FIFO ENABLE at 124, write clock WRCLK at 126, and the selected read clock RDCLK′ at 138 and provides write pointer clock WPC at 112 and read pointer clock RPC at 114. Clock pointer circuit 600 receives FIFO enable signal FIFO ENABLE at 124 and write clock WRCLK at 126 from a circuit, such as clock and data recovery circuit 120, and clock pointer circuit 600 receives the selected read clock RDCLK′ at 138 from a circuit, such as phase selector 136. In one embodiment, clock pointer circuit 600 is similar to clock pointer circuit 134.

Clock pointer circuit 600 includes first flip-flop 602, second flip-flop 604, first write enable latch 606, second write enable latch 608, third flip-flop 610, fourth flip-flop 612, read enable latch 614, write pointer AND gate 616, and read pointer AND gate 618. The output of first flip-flop 602 is electrically coupled to the data input D of second flip-flop 604 via first data path 620. The output of second flip-flop 604 is electrically coupled to the data input D of first write enable latch 606 via second data path 622. The output of first write enable latch 606 is electrically coupled to the data input D of second write enable latch 608 and to one input of write pointer AND gate 616 via third data path 624. The output of second write enable latch 608 is electrically coupled to the data input D of third flip-flop 610 via fourth data path 626. The output of third flip-flop 610 is electrically coupled to the data input D of fourth flip-flop 612 via fifth data path 628. The output of fourth flip-flop 612 is electrically coupled to the data input D of read enable latch 614 via sixth data path 630. The output of read enable latch 614 is electrically coupled to one input of read pointer AND gate 618 via seventh data path 632.

The data input D of first flip-flop 602 receives FIFO enable signal FIFO ENABLE at 124 and the positive edge triggered clock input of first flip-flop 602 receives write clock WRCLK at 126. Also, the positive edge triggered clock input of second flip-flop 604, the active low latch input of first write enable latch 606, the active high latch input of second write enable latch 608, and an input of write pointer AND gate 616 receive write clock WRCLK at 126. The positive edge triggered clock input of third flip-flop 610 and the positive edge triggered clock input of fourth flip-flop 612 receive the selected read clock RDCLK′ at 138. In addition, the active low latch input of read enable latch 614 and an input of read pointer AND gate 618 receives the selected read clock RDCLK′ at 138.

In operation, clock and data recovery circuit 120 receives input data DIN at 102 and provides a high level FIFO enable signal FIFO ENABLE at 124 that indicates data is being received or will be received. First flip-flop 602 receives the high level FIFO enable signal FIFO ENABLE at 124 and the next positive edge of write clock WRCLK at 126 clocks the high level FIFO enable signal FIFO ENABLE at 124 into first flip-flop 602. Second flip-flop 604 receives the clocked in high level FIFO enable signal at 620 and the next positive edge of write clock WRCLK at 126 clocks the high level FIFO enable signal at 620 into second flip-flop 604. First write enable latch 606 receives the clocked in high level FIFO enable signal at 622 and at the next falling edge and low level of write clock WRCLK at 126, first write enable latch 606 provides a high level write enable signal WR_ENABLE at 624.

Write enable AND gate 616 receives write clock WRCLK at 126 and the high level write enable signal WR_ENABLE at 624 that enables write enable AND gate 616 to provide write pointer clock WPC at 112. Second write enable latch 608 receives the high level write enable signal WR_ENABLE at 624 and at the next rising edge and high level of write clock WRCLK at 126 second write enable latch 608 provides a high level latched write enable signal at 626.

Third flip-flop 610 receives the high level latched write enable signal at 626 and the next positive edge of the selected read clock RDCLK′ at 138 clocks the high level latched write enable signal into third flip-flop 610. Fourth flip-flop 612 receives the clocked in high level signal at 628 and the next positive edge of the selected read clock RDCLK′ at 138 clocks the high level signal at 628 into fourth flip-flop 612. Read enable latch 614 receives the clocked in high level signal at 630 and at the next falling edge and low level of the selected read clock RDCLK′ at 138, read enable latch 614 provides a high level read enable signal RD_ENABLE at 632.

Read enable AND gate 618 receives the selected read clock RDCLK′ at 138 and the high level read enable signal RD_ENABLE at 632 that enables read enable AND gate 618 to provide read pointer clock RPC at 114.

In one embodiment, phase selector 136 selects one of the read clock RDCLKS such that the rising edge of the selected read clock RDCLK′ at 138 is restricted to the low level phase of write clock WRCLK at 126 and clock pointer circuit 600 provides the rising edge of the read pointer clock RPC at 114 restricted to the low level phase of write pointer clock WPC at 112.

In one embodiment, the rising edge of the selected read clock RDCLK′ at 138 relative to the falling edge of write clock WRCLK at 126 is limited to an uncertainty range of within one-half a clock cycle of write clock WRCLK at 126 and the rising edge of read pointer clock RPC at 114 relative to the falling edge of write pointer clock WPC at 112 is limited to the uncertainty range of within one-half a clock cycle of write pointer clock WPC at 112.

In one embodiment, the rising edge of the selected read clock RDCLK′ at 138 relative to the falling edge of write clock WRCLK at 126 is limited to an uncertainty range of within one-fourth a clock cycle of write clock WRCLK at 126 and the rising edge of read pointer clock RPC at 114 relative to the falling edge of write pointer clock WPC at 112 is limited to the uncertainty range of within one-fourth a clock cycle of write pointer clock WPC at 112.

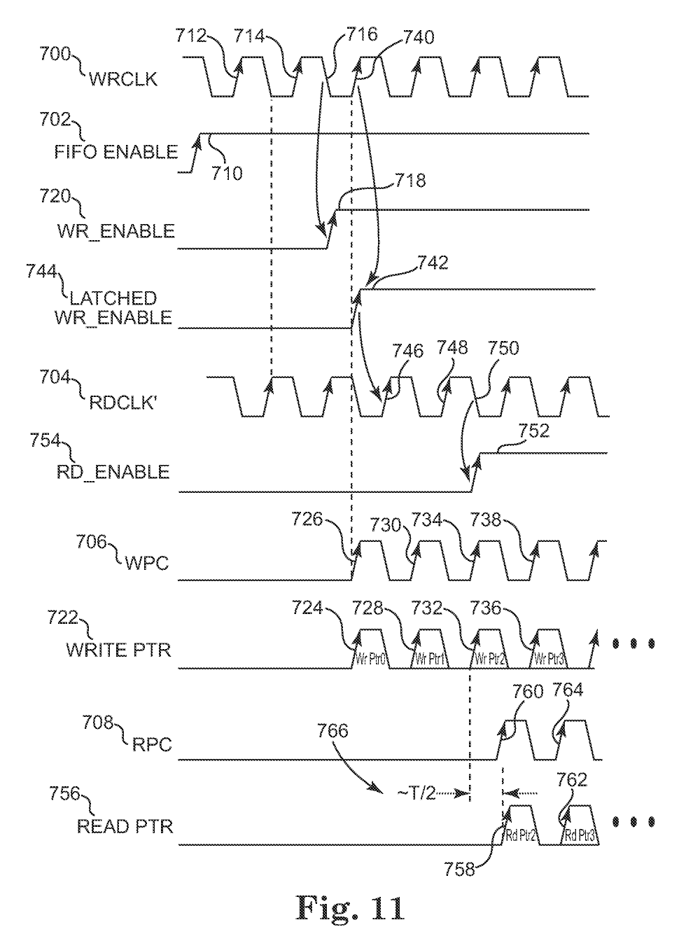

FIG. 11 is a timing diagram illustrating the operation of clock pointer circuit 600, where the resulting spacing between write pointers and read pointers is half a clock period (½ T) of write pointer clock WPC. Clock pointer circuit 600 receives write clock WRCLK at 700, FIFO enable signal FIFO ENABLE at 702, and the selected read clock RDCLK′ at 704 and provides write pointer clock WPC at 706 and read pointer clock RPC at 708. In this example, the rising edge of the selected read clock RDCLK′ at 704 is nearly edge aligned with the falling edge of write clock WRCLK at 700.

Clock and data recovery circuit 120 receives input data DIN at 102 and provides a high level at 710 in FIFO enable signal FIFO ENABLE at 702 that indicates data is being received or will be received. First flip-flop 602 receives the high level at 710 in FIFO enable signal FIFO ENABLE at 702 and the next positive edge at 712 of write clock WRCLK at 700 clocks the high level at 710 into first flip-flop 602. Second flip-flop 604 receives the clocked in high level and the next positive edge at 714 of write clock WRCLK at 700 clocks the high level into second flip-flop 604. First write enable latch 606 receives the clocked in high level and at the next falling edge and low level at 716 of write clock WRCLK at 700, first write enable latch 606 provides a high level at 718 of write enable signal WR_ENABLE at 720. Write enable AND gate 616 receives write clock WRCLK at 700 and the high level at 718 of write enable signal WR_ENABLE at 720 and provides write pointer clock WPC at 706.

Write pointer clock WPC at 706 is used to provide write pointers WRITE PTR at 722, where write pointer 0 at 724 is based on the rising edge at 726, write pointer 1 at 728 is based on the rising edge at 730, write pointer 2 at 732 is based on the rising edge at 734, write pointer 3 at 736 is based on the rising edge at 738, and so on, up to the pointer limit at which point the write pointers WRITE PTR at 722 begin again with write pointer 0.

Second write enable latch 608 receives the high level write enable signal WR_ENABLE at 720 and at the next rising edge and high level at 740 of write clock WRCLK at 700 second write enable latch 608 provides a high level at 742 of latched write enable signal LATCHED WR_ENABLE at 744. Third flip-flop 610 receives the high level at 742 and the next positive edge at 746 of the selected read clock RDCLK′ at 704 clocks the high level at 742 into third flip-flop 610. Fourth flip-flop 612 receives the clocked in high level and the next positive edge at 748 of the selected read clock RDCLK′ at 704 clocks the high level into fourth flip-flop 612. Read enable latch 614 receives the clocked in high level and at the next falling edge and low level at 750 of the selected read clock RDCLK′ at 704, read enable latch 614 provides a high level at 752 of read enable signal RD_ENABLE at 754. Read enable AND gate 618 receives the selected read clock RDCLK′ at 704 and the high level at 752 of read enable signal RD_ENABLE at 754 and provides read pointer clock RPC at 708.

Read pointer clock RPC at 708 is used to provide read pointers READ PTR at 756, where read pointer 2 at 758 is based on the rising edge at 760, read pointer 3 at 762 is based on the rising edge at 764, and so on, up to the pointer limit at which point the read pointers READ PTR at 756 begin again with read pointer 0.

The resulting spacing between write pointers WRITE PTR at 722 and read pointers READ PTR at 756 is about one half a clock period (½ T) of write pointer clock WPC at 706, indicated at 766.

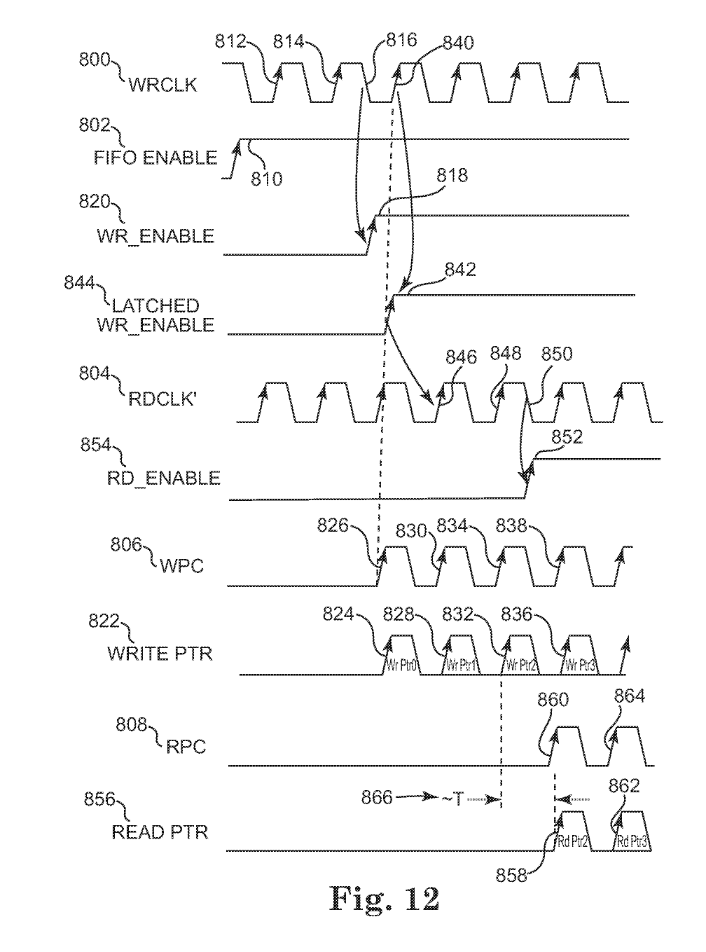

FIG. 12 is a timing diagram illustrating the operation of clock pointer circuit 600, where the resulting spacing between write pointers and read pointers is about one clock period T of write pointer clock WPC. Clock pointer circuit 600 receives write clock WRCLK at 800, FIFO enable signal FIFO ENABLE at 802, and the selected read clock RDCLK′ at 804 and provides write pointer clock WPC at 806 and read pointer clock RPC at 808. In this example, the rising edge of the selected read clock RDCLK′ at 804 is nearly edge aligned with the rising edge of write clock WRCLK at 800.

Clock and data recovery circuit 120 receives input data DIN at 102 and provides a high level at 810 in FIFO enable signal FIFO ENABLE at 802 that indicates data is being received or will be received. First flip-flop 602 receives the high level at 810 in FIFO enable signal FIFO ENABLE at 802 and the next positive edge at 812 of write clock WRCLK at 800 clocks the high level at 810 into first flip-flop 602. Second flip-flop 604 receives the clocked in high level and the next positive edge at 814 of write clock WRCLK at 800 clocks the high level into second flip-flop 604. First write enable latch 606 receives the clocked in high level and at the next falling edge and low level at 816 of write clock WRCLK at 800, first write enable latch 606 provides a high level at 818 of write enable signal WR_ENABLE at 820. Write enable AND gate 616 receives write clock WRCLK at 800 and the high level at 818 of write enable signal WR_ENABLE at 820 and provides write pointer clock WPC at 806.

Write pointer clock WPC at 806 is used to provide write pointers WRITE PTR at 822, where write pointer 0 at 824 is based on the rising edge at 826, write pointer 1 at 828 is based on the rising edge at 830, write pointer 2 at 832 is based on the rising edge at 834, write pointer 3 at 836 is based on the rising edge at 838, and so on, up to the pointer limit at which point the write pointers WRITE PTR at 822 begin again with write pointer 0.

Second write enable latch 608 receives the high level at 818 of write enable signal WR_ENABLE at 820 and at the next rising edge and high level at 840 of write clock WRCLK at 800 second write enable latch 608 provides a high level at 842 of latched write enable signal LATCHED WR_ENABLE at 844. Third flip-flop 610 receives the high level at 842 and the next positive edge at 846 of the selected read clock RDCLK′ at 804 clocks the high level at 842 into third flip-flop 610. Fourth flip-flop 612 receives the clocked in high level and the next positive edge at 848 of the selected read clock RDCLK′ at 804 clocks the high level into fourth flip-flop 612. Read enable latch 614 receives the clocked in high level and at the next falling edge and low level at 850 of the selected read clock RDCLK′ at 804, read enable latch 614 provides a high level at 852 of read enable signal RD ENABLE at 854. Read enable AND gate 618 receives the selected read clock RDCLK′ at 804 and the high level at 852 of read enable signal RD_ENABLE at 854 and provides read pointer clock RPC at 808.

Read pointer clock RPC at 808 is used to provide read pointers READ PTR at 856, where read pointer 2 at 858 is based on the rising edge at 860, read pointer 3 at 862 is based on the rising edge at 864, and so on, up to the pointer limit at which point the read pointers READ PTR at 856 begin again with read pointer 0.

The resulting spacing between write pointers WRITE PTR at 822 and read pointers READ PTR at 856 is about one clock period T of write pointer clock WPC at 806, indicated at 866.

Phase selector 136 and clock pointer circuits 134 and 600 limit the uncertainty range of the phase relationship between the read pointer clock RPC and the write pointer clock WPC to within one-half a full clock cycle. The reduced pointer uncertainty range decreases data latency through the FIFO, which is critical to the operation of electronic systems in some applications, such as FB-DIMM applications.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a first circuit configured to obtain a sample of a first clock via a second clock and provide a selected clock from multiple clocks based on the sample; and
a second circuit configured to provide a first pointer clock based on the first clock and a second pointer clock based on the selected clock, wherein an edge of the second pointer clock relative to an edge of the first pointer clock is limited to an uncertainty range of within one-half a first pointer clock cycle.

2. The integrated circuit of claim 1, wherein the multiple clocks include the second clock and a third clock that is 180 degrees out of phase with the second clock.

3. The integrated circuit of claim 2, wherein the first circuit is configured to select between the second clock and the third clock to provide the selected clock and limit the uncertainty range of the edge of the second pointer clock relative to the edge of the first pointer clock to within one-half the first pointer clock cycle.

4. The integrated circuit of claim 2, wherein the multiple clocks include a fourth clock that is 90 degrees out of phase with the second clock and a fifth clock that is 270 degrees out of phase with the second clock.

5. The integrated circuit of claim 4, wherein the first circuit is configured to select between the second clock, the third clock, the fourth clock, and the fifth clock to provide the selected clock and limit the uncertainty range of the edge of the second pointer clock relative to the edge of the first pointer clock to within one-fourth the first pointer clock cycle.

6. The integrated circuit of claim 1, wherein the first clock is in a first clock domain and the multiple clocks are in a second clock domain and the multiple clocks include the second clock.

7. The integrated circuit of claim 1, wherein the second circuit is configured to clock an enable signal into the second circuit via the first clock to provide a first enable signal that enables the first pointer clock.

8. The integrated circuit of claim 7, wherein the second circuit is configured to clock the first enable signal into the second circuit via the selected clock to provide a second enable signal that enables the second pointer clock.

9. The integrated circuit of claim 7, wherein the second circuit is configured to latch the first enable signal into the second circuit via the first clock to provide a latched first enable signal and the second circuit clocks the latched first enable signal into the second circuit via the selected clock to provide a second enable signal that enables the second pointer clock.

10. An electronic system comprising:
an advanced memory buffer including:
a first in first out memory;
a first circuit configured to obtain a sample of a first clock in a first clock domain via a second clock in a second clock domain and provide one of multiple clocks in the second clock domain based on the sample; and
a second circuit configured to provide a write pointer clock based on the first clock and a read pointer clock based on the one of the multiple clocks, wherein data is written into the first in first out memory via the write pointer clock in the first clock domain and data is read from the first in first out memory via the read pointer clock in the second clock domain and an edge of the read pointer clock relative to an edge of the write pointer clock is limited to an uncertainty range within one-half a write pointer clock cycle.

11. The electronic system of claim 10, wherein an edge of the one of the multiple clocks relative to an edge of the first clock is limited to the uncertainty range of within one-half the write pointer clock cycle.

12. The electronic system of claim 10, wherein an edge of the one of the multiple clocks relative to an edge of the first clock is limited to an uncertainty range of within one-fourth the write pointer clock cycle.

13. The electronic system of claim 12, wherein the edge of the read pointer clock relative to the edge of the write pointer clock is limited to the uncertainty range of within one-fourth the write pointer clock cycle.

14. The electronic system of claim 10, wherein the read pointer clock is 360 degrees to 540 degrees out of phase with the write pointer clock.

15. The electronic system of claim 10, wherein the read pointer clock is 180 degrees to 360 degrees out of phase with the write pointer clock.

16. A method of operating an integrated circuit comprising:
obtaining a sample of a first clock via a second clock;
selecting one clock from multiple clocks based on the sample such that an edge of the one clock relative to an edge of the first clock is within an uncertainty range of one-half a first clock cycle;
providing a first pointer clock based on the first clock; and
providing a second pointer clock based on the one clock.

17. The method of claim 16, wherein selecting one clock comprises:
selecting one of the second clock and a third clock that is 180 degrees out of phase with the second clock.

18. The method of claim 16, wherein selecting one clock comprises:
selecting one of the second clock, a third clock that is 180 degrees out of phase with the second clock, a fourth clock that is 90 degrees out of phase with the second clock, and a fifth clock that is 270 degrees out of phase with the second clock.

19. The method of claim 16, wherein obtaining a sample comprises:
obtaining the sample of the first clock in a first clock domain via the second clock in a second clock domain.

20. The method of claim 16, wherein providing a first pointer clock comprises:
clocking in an enable signal via the first clock to provide a first enable signal that enables the first pointer clock.

21. The method of claim 20, wherein providing a second pointer clock comprises:
clocking in the first enable signal via the one clock to provide a second enable signal that enables the second pointer clock.

22. The method of claim 20, wherein providing a second pointer clock comprises:
latching in the first enable signal via the first clock to provide a latched first enable signal; and
clocking in the latched first enable signal via the one clock to provide a second enable signal that enables the second pointer clock.

23. A method of operating an electronic system comprising:
obtaining a sample of a first clock in a first clock domain via a second clock in a second clock domain;
selecting one clock from multiple clocks in the second clock domain based on the sample such that an edge of the one clock relative to an edge of the first clock is within an uncertainty range of one-half a first clock cycle;
providing a first pointer clock based on the first clock;
providing a second pointer clock based on the one clock;
writing data into a first in first out memory via the first pointer clock in the first clock domain; and
reading data from the first in first out memory via the second pointer clock in the second clock domain.

24. The method of claim 23, wherein selecting one clock comprises:
selecting the one clock from multiple clocks in the second clock domain based on the sample such that the edge of the one clock relative to the edge of the first clock is within an uncertainty range of one-fourth the first clock cycle.

25. The method of claim 23, wherein providing a second pointer clock comprises:
providing the second pointer clock 360 degrees to 540 degrees out of phase with the first pointer clock.
